(19) United States
(12) Patent Application Publication
(10) Pub. No.: US 2026/0316020 A1
(43) Pub. Date: Oct. 15, 2026

(54) SYSTEM AND METHOD FOR INTEGRATED SUPPLY OF COAGULANT RAW MATERIALS

(71) Applicant: SK On Co., Ltd., Seoul (KR)

(72) Inventors: Moon Sang YOU, Daejeon (KR); Yeong Jun JI, Daejeon (KR)

(21) Appl. No.: 19/575,958

(22) Filed: Mar. 24, 2026

(30) Foreign Application Priority Data
Apr. 10, 2025 (KR) 10-2025-0046632

(51) Int. Cl. B01F 25/53; B01F 27/1122; B01F 27/90; B01F 35/21; B01F 35/22; B01F 35/221; B01F 35/71; B01F 101/59

(52) U.S. Cl. CPC B01F 25/53; B01F 27/1122; B01F 27/90; B01F 35/2117; B01F 35/2202; B01F 35/2217; B01F 35/718051; B01F 2101/59

(57) ABSTRACT

A system for integrated supply of coagulant raw materials includes a main storage tank for storing and metering a coagulable raw material; a circulation pumping pipe providing a circulation path of the coagulable raw material from one end of the main storage tank to the other end thereof; an extraction valve for extracting a portion of the coagulable raw material from the circulation pumping pipe when a mixing line for injection thereinto is designated; a metering tank connected to the extraction valve, and metering the coagulable raw material extracted from the extraction valve; and a compressed air injection nozzle connected to the metering tank, and supplying compressed air to the metering tank so that when the coagulable raw material metered in the metering tank reaches a target amount, the metered coagulable raw material is injected into the designated mixing line, after the extraction is stopped.

### CROSS-REFERENCE TO RELATED APPLICATIONS

This application claims benefit of priority to Korean Patent Applications No. 10-2025-0046632 filed on Apr. 10, 2025, in the Korean Intellectual Property Office, the disclosure of which is incorporated herein by reference in its entirety.

### BACKGROUND

### 1. Field

The present disclosure relates to a system and method for integrated supply of coagulant raw materials.

### 2. Description of Related Art

In general, a process of manufacturing a secondary battery includes a process of manufacturing an electrode, and in order to manufacture an electrode, an electrode active material may be coated on a positive electrode current collector or a negative electrode current collector acting as a substrate, and an electrode slurry for coating the electrode active material is required. The electrode slurry is made in a slurry mixer receiving a coagulable raw material such as a binder, a solvent, or the like, from a device for supply of coagulable raw materials.

The existing device for supply of coagulable raw materials stores a raw material in a storage tank connected to a batch mixer, which is a raw material injection destination, by through a worker manually adding the raw material in a required amount. In this case, when the raw material is injected, an appropriate amount of raw material is extracted from the raw material stored in the storage tank through an injection pipe, and then compressed air is supplied to the injection pipe, and the raw material extracted through the injection pipe is injected into the batch mixer.

Meanwhile, the coagulant raw materials used in the process of manufacturing a secondary battery have coagulant properties that harden when stored at room temperature for a long period of time, so careful attention is required during the injection process.

### SUMMARY

An aspect of the present disclosure is to provide a system and method for integrated supply of coagulant raw materials, automatically extracting, metering, and injecting a coagulant raw material (e.g. a binder) into a slurry mixer during a process of producing a slurry for electrodes of secondary batteries.

The technical solutions of the present disclosure are not limited to those mentioned above, and other technical solutions not mentioned will be clearly understood by a person skilled in the art of the present disclosure from the description below.

According to an aspect of the present disclosure, provided is a system for integrated supply of coagulant raw materials, the system including: a main storage tank for storing and metering a coagulant raw material; a circulation pumping pipe providing a circulation path of the coagulable raw material from one end of the main storage tank to the other end thereof; an extraction valve for extracting a portion of the coagulable raw material from the circulation pumping pipe, for injection into a designated mixing line when a mixing line for injection thereinto is designated; a metering tank connected to the extraction valve, and metering the coagulable raw material extracted from the extraction valve; and a compressed air injection nozzle connected to the metering tank, and supplying compressed air to the metering tank so that when the coagulable raw material metered in the metering tank reaches a target amount, the metered coagulable raw material is injected into the designated mixing line, after the extraction is stopped.

The system for integrated supply of coagulant raw materials is configured to further include: a control device controlling loop line circulation, extraction and metering, and injection of the coagulable raw material, when a supply process of the coagulable raw material is initiated.

The main storage tank is configured to include: a stirrer disposed inside the main storage tank to stir a coagulable raw material stored in the main storage tank; and a first weight measuring device for measuring a weight of the coagulable raw material stored in the main storage tank.

The circulation pumping pipe is configured to include: a circulation pipe connected from one end of the main storage tank to the other end thereof, and providing a loop line for circulation of the coagulable raw material stored in the main storage tank; and a circulation pump disposed in the circulation pipe, and pumping the coagulable raw material from the main storage tank to circulate through the circulation pipe.

The extraction valve is configured to include: a branch pipe connected to a lower portion of the circulation pumping pipe in different locations thereof; a branch valve disposed in the branch pipe, to open and close the branch pipe; and a flexible pipe disposed in front of the branch valve, to flexibly connect the branch pipe from the influence of a weight of the circulation pumping pipe.

The metering tank is configured to include: a metering storage tank connected to the extraction valve, and storing a coagulable raw material introduced through the extraction valve; a second weight measuring device measuring a weight of the coagulable raw material stored in the metering storage tank; a discharge pipe connected to one side of the metering storage tank, and discharging the metered coagulable raw material to a connected mixer; and a metering valve disposed in the discharge pipe, and operating to be opened and closed for metering and discharging the coagulable raw material.

The compressed air injection nozzle is configured to include: an air injection nozzle connected between an inlet of the metering tank and a compressed air tank and injecting compressed air; and an air control valve disposed in the air injection nozzle, and opening and closing the air injection nozzle.

The control device is configured to include: a first controller, controlling circulation of a coagulable raw material through the circulation pumping pipe, when a supply process of the coagulable raw material is initiated; a second controller, controlling extraction and metering of the coagulable raw material through the extraction valve and the metering tank, in relation to the corresponding mixing line, according to an injection request for the corresponding mixing line; and a third controller, controlling injection of the coagulable raw material through the compressed air injection nozzle, in relation to the corresponding mixing line, when the metering is normally completed.

In addition, according to another aspect of the present disclosure, provided is a method for integrated supply of coagulable raw materials, the method including: performing a circulation pumping operation of performing mixing of a coagulable raw material stored in a main storage tank, and performing circulation of the coagulable raw material through a circulation pumping pipe, when a supply process of the coagulable raw material is initiated; performing an injection request confirmation operation of confirming designation of a mixing line to be metered, when an injection request for a specific mixing line has been received; performing a metering operation of performing extraction and metering through an extraction valve and a metering tank, for the designated mixing line; and performing an injection operation of performing injection of the coagulable raw material into the corresponding mixing line using compressed air, when the metering is normally completed.

The circulation pumping operation is configured to include: a circulation pumping operation of initiating an operation of a circulation pump to circulate the coagulable raw material through a circulation pipe of the circulation pumping pipe, when a supply process of the coagulable raw material is initiated; and a circulation maintenance operation of maintaining loop line circulation through the circulation pipe and the circulation pump.

The injection request confirmation operation is configured to include: an injection request confirmation operation for determining whether an injection request for a specific mixing line has been received from a mixing control system; and a mixing line designation confirmation operation of confirming destination of the mixing line to be metered, when the injection request for a specific mixing line has been received.

The metering operation is configured to include: an extraction valve opening operation, opening an extraction valve, in relation to the corresponding mixing line; a first metering verification operation, initiating metering of a coagulable raw material through the extraction valve, and performing first verification based on a first metering value for the coagulable raw material in the main storage tank; and a second metering verification operation, performing second verification based on a second metering value for the coagulable raw material in the metering tank, when the first verification is normal.

The injection operation is configured to include: an extraction stop operation, performing closing of the extraction valve in relation to the corresponding mixing line, when the metering is normally completed; an air valve opening operation, performing opening of an air control valve connected to an air injection nozzle connected to an inlet of the metering tank; and a coagulable raw material injection operation, injecting compressed air through the open air injection nozzle into the metering tank, and performing injection of the coagulable raw material in the metering tank into the designated mixing line.

In addition, aspects of the present disclosure are not limited to the aspects exemplified above, and other aspects may be additionally understood during the course of the description below.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic configuration diagram illustrating a system for integrated supply of coagulable raw materials according to an embodiment of the present disclosure;

FIG. 2 is an example diagram of a control device;

FIG. 3 is an example diagram of a storage tank;

FIG. 4 is an example diagram of a circulation pumping pipe;

FIG. 5 is an example diagram of an extraction pipe;

FIG. 6 is an example diagram of a metering tank;

FIG. 7 is an example diagram of the configuration of a control device;

FIG. 8 is a flowchart illustrating a method for integrated supply of coagulable raw materials according to an embodiment of the present disclosure; and

FIG. 9 is a block diagram of a computing device capable of fully or partially implementing a system for integrated supply and method for coagulable raw materials according to an embodiment of the present disclosure.

In the illustrated embodiment, each component may have different functions and capabilities other than those described below, and may include additional components other than those described below.

In drawings and detailed descriptions, the same reference numerals may refer to the same components. Drawings may not be to scale, and the relative sizes, proportions, and depictions of drawing elements may be enlarged or reduced from actual size for clarity, explanation, and convenience.

### DETAILED DESCRIPTION

Since the present disclosure may have various changes and may have various exemplary embodiments of the present disclosure, specific embodiments may be illustrated in the drawings and described in detail. However, this is not intended to limit the present disclosure to specific embodiments, it should be understood to include all modifications, equivalents, and substitutes included in the spirit and technical scope of the present disclosure.

Terms such as first, second, and the like may be used to describe various elements, but the elements should not be limited by the terms. The above terms may be used only for distinguishing one component from another. For example, without departing from the scope of the present disclosure, a first component may be referred to as a second component, and similarly, a second component may also be referred to as a first component. The term “and/or” may include a combination of a plurality of related listed items or any of the plurality of related listed items.

The terms used in the present application may be only used to describe specific embodiments, and are not intended to limit the present disclosure. The singular expression may include the plural expression, unless the context clearly dictates otherwise. In the present application, it should be understood that terms such as “include,” “comprise,” or “have” are intended to designate that features, numerals, steps, operations, components, parts, or combination thereof described in the specification exists, but one or more other features this does not preclude the existence or addition of numbers, steps, operations, components, parts, or combinations thereof.

Unless defined otherwise, all terms used herein, including technical or scientific terms, have the same meaning as that which can commonly understood by one of ordinary skill in the art to which the present disclosure belongs. Terms such as those defined in a commonly used dictionary should be interpreted as having a meaning consistent with the meaning in the context of the related art, and should not be interpreted in an ideal or excessively formal manner unless explicitly defined in the present application.

Hereinafter, with reference to the attached drawings, embodiments of the present disclosure will be described in more detail.

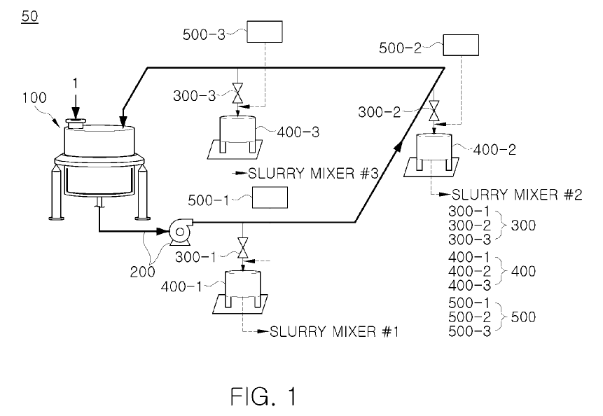

FIG. 1 is a schematic configuration diagram illustrating a system for integrated supply of coagulable raw materials according to an embodiment of the present disclosure.

Referring to FIG. 1, a system for integrated supply for coagulable raw materials 50 according to an embodiment of the present disclosure may include a main storage tank 100, a circulation pumping pipe 200, an extraction valve 300, a metering tank 400, and a compressed air injection nozzle 500.

For example, the main storage tank 100 may store and meter a coagulable raw material for an electrode of a secondary battery 1.

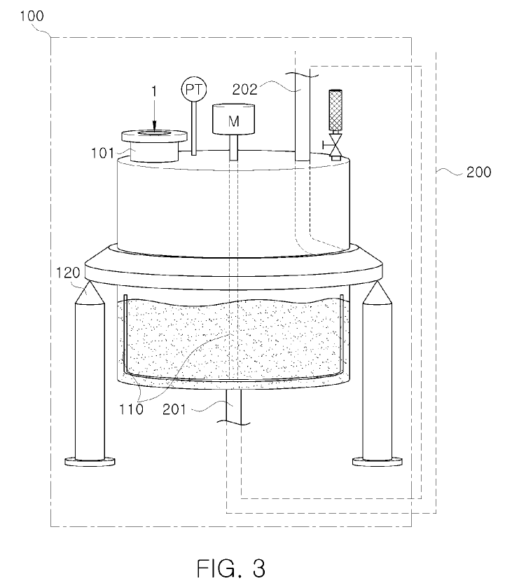

For example, the coagulable raw material for an electrode 1 may be a binder or solvent required for producing an electrode slurry. The main storage tank 100 includes an internal stirring structure and operates to prevent the stored coagulable raw material 1 from coagulating, which will be further described with reference to FIG. 3.

For example, the circulation pumping pipe 200 may provide a circulation path of the coagulable raw material from one end of the main storage tank 100 to the other end thereof, and may circulate the coagulable raw material 1 of the main storage tank 100.

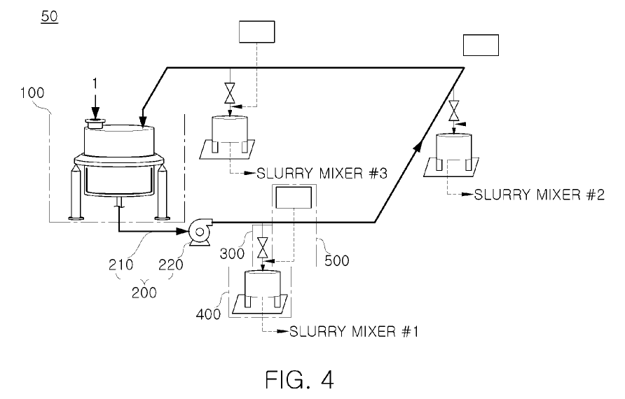

For example, the circulation pumping pipe 200 may be configured to always circulate the coagulable raw material when the process is initiated, taking into account the characteristics of the coagulable raw material having coagulant properties during storage, which will be further described with reference to FIG. 4.

For example, the extraction valve 300 may extract a portion of the coagulable raw material 1 from the circulation pumping pipe 200, for injection into a designated mixing line when a mixing line is designated.

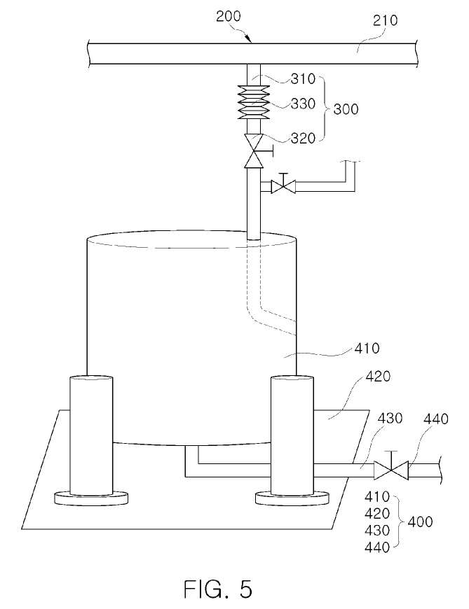

For example, the extraction valve 300 may be connected to a plurality of slurry mixers in a 1:1 correspondence, and may include a plurality of extraction valves 300-1 to 300-3 connected to the circulation pumping pipe 200, and extracting a portion of the coagulable raw material 1 from different locations of the circulation pumping pipe 200. Hereinafter, in the present disclosure, for convenience of explanation and understanding, the extraction valve 300 is described with reference to FIG. 5 as a representative of the plurality of extraction valves 300-1 to 300-3.

Although three extraction valves 300-1 to 300-3 are illustrated in FIG. 1, this is merely an exemplary illustration for explanation and understanding, and an embodiment thereof is not limited thereto. The extraction valve 300 will be further described with reference to FIG. 5.

For example, a metering tank 400 may be connected to the extraction valve 300, and may meter the coagulable raw material extracted from the extraction valve 300.

For example, the metering tank 400 may include a plurality of metering tanks 400-1 to 400-3 connected to the plurality of extraction valves 300-1 to 300-3 in a 1:1 correspondence, and metering the coagulable raw material extracted from each of the plurality of extraction valves 300-1 to 300-3. Hereinafter, in the present disclosure, for convenience of explanation and understanding, the metering tank 400 is described as a representative of the plurality of metering tanks 400-1 to 400-3.

Although three metering tanks 400-1 to 400-3 are illustrated in FIG. 1, this is merely an exemplary illustration for explanation and understanding, and an embodiment thereof is not limited thereto. The metering tank 400 will be further described with reference to FIG. 5.

For example, the compressed air injection nozzle 500 may be connected to the metering tank 400, and may supply compressed air to the metering tank so that when the coagulable raw material metered in the metering tank reaches a target amount, the metered coagulable raw material is injected into the designated mixing line, after the extraction is stopped.

For example, the compressed air injection nozzle 500 may include a plurality of compressed air injection nozzles 500-1 to 500-3 connected to a side of an inlet of each of the plurality of metering tanks 400-1 to 400-3, i.e., a side of an inlet connected to the plurality of extraction valves 300-1 to 300-3, in a 1:1 correspondence to each of the plurality of metering tanks 400-1 to 400-3, and each of the plurality of compressed air injection nozzles 500-1 to 500-3 may inject the metered coagulable raw material into the designated mixing line using compressed air, after the extraction is stopped, when the metered coagulable raw material in the corresponding measuring tank 400-1, 400-2, or 400-3 reaches a target amount. Hereinafter, in the present disclosure, for convenience of explanation and understanding, the compressed air injection nozzle 500 is described as a representative of the plurality of compressed air injection nozzles 500-1 to 500-3.

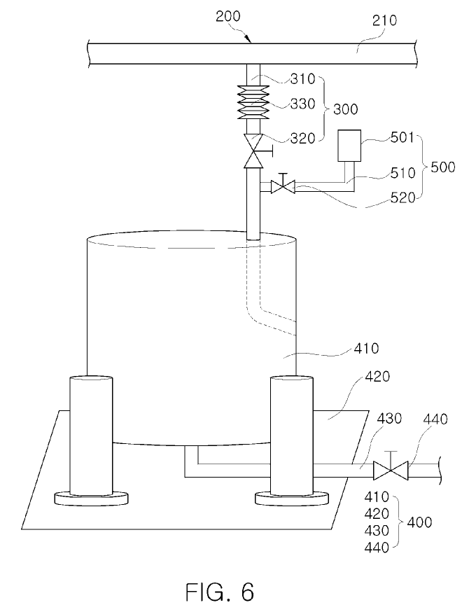

Although three compressed air injection nozzles 500-1 to 500-3 are illustrated in FIG. 1, this is merely an exemplary illustration for explanation and understanding, and an embodiment thereof is not limited thereto. The compressed air injection nozzle 500 will be further described with reference to FIG. 6.

For each drawing of the present disclosure, unnecessary redundant descriptions of components with the same symbols and functions may be omitted, and possible differences between each drawing may be described.

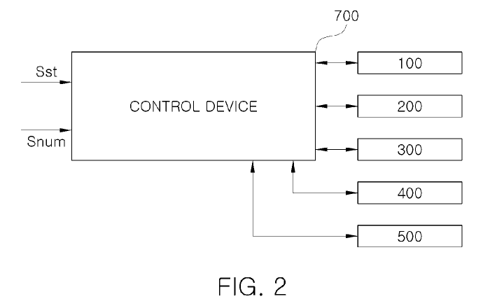

FIG. 2 is an example diagram for a control device.

Referring to FIG. 2, a system of integrated supply 50 of coagulant raw materials according to an embodiment of the present disclosure may include a control device 700.

For example, when a supply process of the coagulable raw material is initiated, the control device 700 may control loop line circulation, extraction and metering, and injection of the coagulable raw material 1.

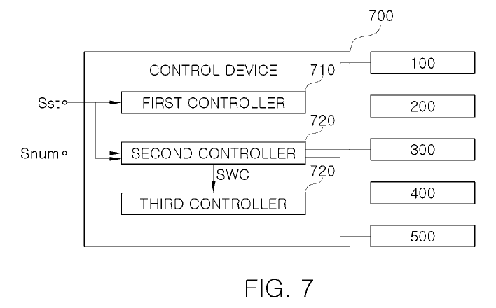

For example, the control device 700 may recognize the initiation of the supply process of the coagulant raw material based on a process initiation signal (Sst), perform control on loop line circulation for the coagulant raw material 1, and perform controlling of extraction and metering, and injection for a designated mixing line, based on a mixing line designation signal (Snum). For example, the process initiation signal (Sst) and the mixing line designation signal (Snum) may be signals provided from an injection device, an operating device, or another subject device. The control device 700 is further described with reference to FIG. 7.

In the present disclosure, the control device 700 may be implemented using at least one processor or computing device.

FIG. 3 is an example diagram of a storage tank.

Referring to FIG. 3, the main storage tank 100 may include a stirrer 110 and a first weight measuring device 120.

For example, the stirrer 110 may be disposed inside the main storage tank 100 to stir a coagulable raw material stored in the main storage tank 100. For example, the stirrer 110 may be an anchor-type stirrer including a motor that operates under the control of the control device 700 and an anchor that stirs the coagulable raw material stored in the main storage tank 100 by the motor, but an embodiment thereof is not limited thereto.

For example, the first weight measuring device 120 may measure a weight of the coagulable raw material 1 stored in the main storage tank 100.

For example, the first weight measuring device 120 may measure a difference between a weight of the main storage tank 100 empty of the coagulable raw material and the weight of the main storage tank 100 after the coagulable raw material is introduced through an inlet 101, as a weight of the coagulable raw material. For example, the first weight measuring device 120 may be a load cell installed to measure the weight of the main storage tank 100, but an embodiment thereof is not limited thereto.

In addition, one end (e.g., an outlet pipe 201) of a circulation pumping pipe 200 may be connected to a lower surface of the main storage tank 100, and the other end (e.g., an inlet pipe 202) of the circulation pumping pipe 200 may be connected to an upper surface of the main storage tank 100. One end 201 of the circulation pumping pipe 200 may be an outlet pipe through which a coagulable raw material 1 is discharged, and the other end 202 of the circulation pumping pipe 200 may be an inlet pipe through which the coagulable raw material 1 is introduced. Depending on a connection structure of the circulation pumping pipe 200, the circulation of the coagulable raw material may be performed more smoothly.

FIG. 4 is an example diagram of a circulation pumping pipe.

Referring to FIG. 4, the circulation pumping pipe 200 may include a circulation pipe 210 and a circulation pump 220.

For example, the circulation pipe 210 may be connected from one end of the main storage tank 100 to the other end thereof, to provide a loop line for circulation of the coagulable raw material stored in the main storage tank 100. For example, the circulation pipe 210 may include an outlet pipe 201 connected to one end of the main storage tank 100 to discharge a coagulable raw material 1, and an inlet pipe 202 connected from one end of the main storage tank 100 to the other end thereof, to introduce the coagulable raw material 1.

For example, the circulation pump 220 may be disposed in the circulation pipe 210, and perform a pumping operation so that the coagulable raw material 1 from the main storage tank 100 circulates through the circulation pipe 210.

Meanwhile, a valve that can be opened and closed can be installed in the outlet pipe 201 and the inlet pipe 202 of the circulation pipe 210 connected to the main storage tank 100, and this valve may be in a closed state before a circulation pumping operation starts, and may be in an open state during the circulation pumping operation.

FIG. 5 is an example diagram of an extraction pipe.

Referring to FIG. 5, the extraction valve 300 may include a branch pipe 310, a branch valve 320, and a flexible pipe 330.

For example, the branch pipe 310 may be connected to a lower portion of the circulation pumping pipe 200 in different locations thereof. For example, the branch pipe 310 may be connected to a lower end of the circulation pumping pipe 200, so that a portion of a coagulable raw material may be extracted from the circulation pumping pipe 200 and provided to the metering tank 400.

For example, a branch valve 320 may be disposed in the branch pipe 310 to open and close the branch pipe 310. For example, the branch valve 320 may be controlled to be opened or closed under the control of the control device 700, thereby controlling the capacity of the coagulable raw material extracted through the branch pipe 310.

For example, a flexible pipe 330 may be disposed in front of the branch valve 320 to flexibly connect the circulation pumping pipe 200. For example, the flexible pipe 330 may be formed of a hose pipe having a flexible corrugated structure whose length is adjusted by contraction and expansion, and accordingly, when metering in a metering tank 400 connected to the branch pipe 310, the metering tank 400 may accurately measure a weight of the coagulable raw material included in the branch pipe 310 and the metering tank 400 independently without relying on a weight of the circulation pumping pipe 200.

In addition, referring to FIG. 5, the metering tank 400 may include a metering storage tank 410, a second weight measuring device 420, a discharge pipe 430, and a metering valve 440.

For example, the metering storage tank 410 may be connected to the extraction valve 300 and store a coagulable raw material introduced through the extraction valve 300.

For example, the second weight measuring device 420 may measure a weight of the coagulant raw material stored in the metering storage tank 410. For example, the second weight measuring device 420 may measure a difference between the weight of the metering storage tank 410 empty of the coagulable raw material and the weight of the metering storage tank 410 into which the coagulable raw material has been injected, as the weight of the extracted coagulable raw material. For example, the second weight measuring device 420 may be a floor-type scale supporting the metering storage tank 410.

For example, the discharge pipe 430 may be connected to one side of the metering storage tank 410, to discharge the measured coagulable raw material to the connected mixer. For example, the discharge pipe 430 may be connected to a bottom surface the metering storage tank 410, and in this case, the coagulable raw material stored in the metering storage tank 410 may be smoothly discharged.

For example, a metering valve 440 may be disposed in the discharge pipe 430, and may perform opening and closing operations to meter and discharge the coagulant raw material. For example, the metering valve 440 may be closed when metering the coagulable raw material, and may be opened when discharging the coagulable raw material, under the control of the control device 700.

FIG. 6 is an example diagram for a metering tank.

Referring to FIG. 6, the compressed air injection nozzle 500 may include a compressed air tank 501, an air injection nozzle 510, and an air control valve 520.

For example, the compressed air tank 501 stores compressed air to be injected into the metering storage tank 410.

For example, an air injection nozzle 510 may be connected between an inlet of the metering tank 400 and a compressed air tank 501, so that compressed air supplied from the compressed air tank 501 may be injected into the metering tank 400 through the inlet of the metering tank 400. Accordingly, the inlet of the metering tank 400 and the coagulable raw material in the metering tank 400 may be discharged to the mixer through the discharge pipe 430. The mixer may be a slurry mixer for producing slurry.

For example, the air control valve 520 may be disposed on the air injection nozzle 510, to open and close the air injection nozzle 510. For example, the air control valve 520 may be closed when metering coagulable raw materials in the metering tank 400, and may be opened when discharging coagulable raw materials from the metering tank 400, under the control of a control device 700.

FIG. 7 is an example diagram of the configuration of a control device.

Referring to FIG. 7, the control device 700 may include a first controller 710, a second controller 720, and a third controller 730.

For example, when a supply process of a coagulable raw material is initiated (Sst), the first controller 710 may control the circulation of the coagulable raw material 1 through the circulation pumping pipe 200. For example, the first controller 710 may control the circulation pumping pipe 200 for the circulation of the coagulant raw material, based on a process initiation signal (Sst) input when the supply process of the coagulant raw material is initiated.

For example, the second controller 720 may control extraction and metering of the coagulable raw material through the extraction valve 300 and the metering tank 400 in relation to the corresponding mixing line, according to an injection request (Snum) for the corresponding mixing line. For example, the second controller 720 may control the extraction valve 300 and the metering tank 400 connected to the corresponding mixing line for the extraction and metering of the coagulant raw material according to the injection request signal (Snum) for the corresponding mixing line, and when the metering is normally completed, may output a metering completion signal (Swc) to a third controller 730.

For example, when the metering is normally completed (Swc), the third controller 730 may control injection of the coagulable raw material through the compressed air injection nozzle 500 in relation to the corresponding mixing line. For example, the third controller 730 may control injection of compressed air through the compressed air injection nozzle 500 for injection the coagulant raw material into the corresponding mixing line based on the metering completion signal (Swc).

In the present disclosure, each of the first controller 710, the second controller 720, and the third controller 730 may be implemented as individual processors, or may be implemented as one processor, and there is no need to be particularly limited to any one thereof.

In addition, each of the first controller 710, the second controller 720, and the third controller 730 may be implemented as hardware element(s) or software element(s) or a combination thereof in at least one integrated circuit (IC) built into the control device 700, and is not particularly limited to any one thereof.

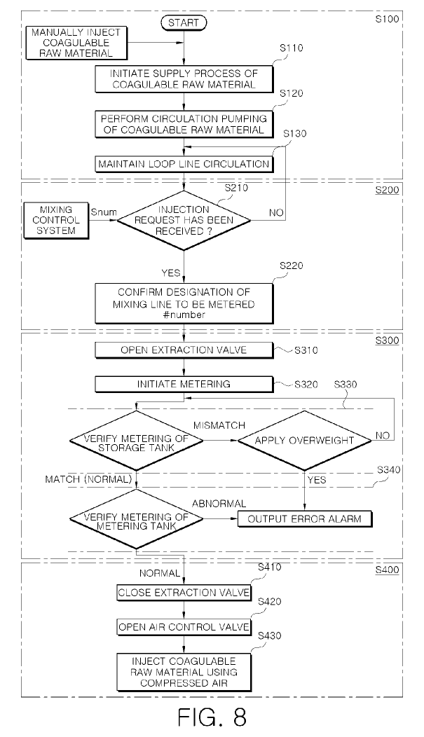

Hereinafter, with reference to FIG. 8, a method for integrated supply for coagulant raw materials will be described. In the present disclosure, the description of the method for integrated supply for coagulable raw materials and the description of the system for integrated supply of coagulable raw materials may be complementary or commonly applied to parts that can be equally applied, unless there are mutually exclusive circumstances.

Accordingly, redundant descriptions may be omitted. Hereinafter, the main processes for the method for integrated supply of coagulant raw materials are described.

FIG. 8 is a flowchart illustrating a method for integrated supply of coagulable raw materials according to an embodiment of the present disclosure.

Referring to FIG. 8, the method for integrated supply of coagulable raw materials according to an embodiment of the present disclosure may be executed by the system for integrated supply of coagulable raw materials 50 illustrated in FIG. 1, and the method for integrated supply of coagulant raw materials may include a circulation pumping operation (S100), an injection request confirmation operation (S200), a metering operation (S300), and an injection operation (S400).

For example, in the circulation pumping operation (S100), the system for integrated supply of coagulable raw materials 50 (see FIG. 1) may perform mixing of the coagulable raw material stored in the main storage tank 100, and perform circulating of the coagulable raw material 1 through the circulation pumping pipe 200 when the supply process of the coagulable raw material is initiated (Sst).

In the injection request confirmation operation (S200), the system for integrated supply of coagulable raw materials 50 (see FIG. 1) may confirm the designation of a mixing line to be metered when an injection request for a specific mixing line has been received.

In the metering operation (S300), the system for integrated supply of coagulable raw materials 50 (see FIG. 1) may perform extraction and metering for the designated mixing line through the extraction valve 300 and the metering tank 400.

For example, in the injection operation (S400), the system for integrated supply of coagulable raw materials 50 (see FIG. 1) may perform injection of the coagulable raw material into the corresponding mixing line using compressed air through a compressed air injection nozzle 500 when the metering is normally completed (Swc).

Referring to FIG. 8, the circulation pumping operation (S100) may include circulation pumping operations (S110 and S120) and a circulation maintenance operation (S130).

For example, in the circulation pumping operations (S110 and S120), the system for integrated supply of coagulable raw materials 50 (see FIG. 1) may initiate an operation the circulation pump 220 to circulate the coagulable raw material 1 through a circulation pipe 210 of the circulation pumping pipe 200, when a supply process of the coagulable raw material is initiated (Sst) (S110) (S120).

For example, in the circulation maintenance operation (S130), the system for integrated supply of coagulable raw materials 50 (see FIG. 1) may maintain loop line circulation through the circulation pipe 210 and the circulation pump 220 until the supply process of the coagulable raw material is completed.

Referring to FIG. 8, the injection request confirmation operation (S200) may include an injection request confirmation operation (S210) and a mixing line designation confirmation operation (S220).

For example, in the injection request confirmation operation (S210), the system for integrated supply of coagulable raw materials 50 (see FIG. 1) may determine whether an injection request (Snum) for a specific mixing line has been received from a mixing control system. For example, when a user designates a mixing line through the mixing control system, it is possible to determine whether an injection request (Snum) signal for a specific mixing line has been received according to the designation of the mixing line.

For example, in the mixing line confirmation designation operation (S220), the system for integrated supply of coagulable raw materials 50 (see FIG. 1) may confirm the designation of a mixing line to be metered, when the injection request has been received.

For example, when the system for integrated supply of coagulable raw materials 50 according to the present disclosure is a system supplying a coagulable raw material to each of first, second third slurry mixers, as illustrated in FIG. 1, the system for integrated supply of coagulable raw materials 50 according to the present disclosure may include first, second, and third extraction valves 310, 320, and 330, first, second, and third metering tanks 410, 420, and 430, and first, second, and third compressed air injection nozzles 510, 520, and 530 related to each of the first, second, and third slurry mixers.

For example, when a first mixing line (mixer #1) is designated, a first extraction pipe 300-1, a first metering tank 400-1, and a first compressed air injection nozzle 500-1 may operate sequentially under the control of the control device 700 to supply a coagulant raw material to the first slurry mixer. As another example, when a second mixing line (mixer #2) is designated, a second extraction pipe 300-2, a second metering tank 400-2, and a second compressed air injection nozzle 500-2 may operate sequentially under the control of the control device 700 to supply the coagulant raw material to the second slurry mixer. As another example, referring to FIG. 1, when a third mixing line (mixer #3) is designated, a third extraction valve 300-3, a third metering tank 400-3, and a third compressed air injection nozzle 500-3 may operate sequentially under the control of the control device 700 to supply coagulant raw material to the third slurry mixer.

In the present disclosure, any one of the first, second, and third mixing lines may be designated, and when any one mixing line is designated, the operation of the extraction valve 300, the metering tank 400, and the compressed air injection nozzle 500 is described, representing each of the corresponding extraction valve, the corresponding metering tank, and the corresponding compressed air injection nozzle.

Referring to FIG. 8, the metering operation (S300) may include an extraction valve opening operation (S310), first metering verification operations (S320 and S330), and a second metering verification operation (S340).

For example, in the extraction valve opening operation (S310), the system for integrated supply of coagulable raw materials 50 (see FIG. 1) may open the extraction valve 300 related to the corresponding mixing line.

For example, in the first metering verification operations (S320 and S330), the system for integrated supply of coagulable raw materials 50 (see FIG. 1) may initiate metering of a coagulable raw material through the extraction valve (S320), and perform first verification based on a first metering value for the coagulable raw material 1 of the main storage tank 100.

To further elaborate thereon, the first metering verification operation is a process of verifying whether the first metering value measured in the storage tank 100 matches a target metering value. In the first metering verification operation, it is checked whether the first metering value matches (normal) the target metering value, and when the first metering value matches the target metering value, a second metering verification operation (S340) proceeds as normal. In contrast, when the first metering value mismatches the target metering value, it is confirmed whether the first metering value is overweight or exceeds the target metering value. When the first metering value is less than the target metering value, rather than being overweight, an extraction process may continue by proceeding to the first metering verification operation (S330), and when the first metering value is overweight, a process of outputting an alarm for overweight may be performed.

For example, in the second metering verification operation (S340), the system for integrated supply of coagulable raw materials 50 (see FIG. 1) may perform a second verification based on a second metering value for the coagulable raw material 1 of the metering tank 400, when the first verification is normal.

To further elaborate thereon, the second metering verification operation is a process of verifying whether the second metering value measured in the metering tank 400 matches a target metering value. In the second metering verification operation, it is checked whether the second metering value matches (normal) the target metering value, and when the second metering value matches the target metering value, a normal injection operation (S400) may proceed as normal. Alternatively, when the second metering value mismatches the target metering value, which is abnormal, a process of outputting alarm may be performed.

In addition, referring to FIG. 8, the injection operation (S400) may include an extraction stop operation (S410), an air valve opening operation (S420), and a coagulant raw material injection operation (S430).

For example, in the extraction stop operation (S410), the system for integrated supply of coagulable raw materials 50 (see FIG. 1) may close the extraction valve 300 in relation to the corresponding to mixing line, when the metering is completed normally.

For example, in the air valve opening operation (S420), the system for integrated supply of coagulable raw materials 50 (see FIG. 1) may open an air control valve 520 connected to an air injection nozzle 510 connected to the inlet of the metering tank 400.

For example, in the coagulable raw material injection operation (S430), the system for integrated supply of coagulable raw materials 50 (see FIG. 1) may inject compressed air through the open air injection nozzle 510 into the extraction valve 300 to inject the coagulable raw material in the extraction valve 300 into the designated mixing line (e.g., the slurry mixer).

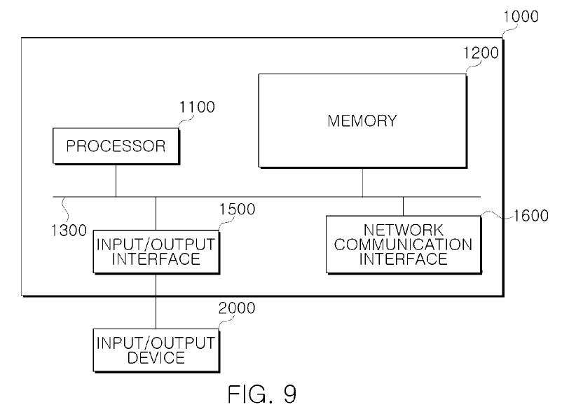

FIG. 9 is a block diagram of a computing device capable of fully or partially implementing a system for integrated supply and method for coagulable raw materials according to an embodiment of the present disclosure.

As illustrated in FIG. 9, a computing device 1000 includes at least one processor 1100, a computer-readable storage medium 1200, and a communication bus 1300.

The processor 1100 may cause the computing device 1000 to operate according to the above-described exemplary embodiments. For example, the processor 1100 may execute one or more programs store in the computer-readable storage medium 1200. The one or more programs may include one or more computer executable instructions, wherein, when executed by the processor 1100, the computer-readable executable instructions may be configured to cause the computing device 1000 to perform operations according to an exemplary embodiment.

The computer-readable storage medium 1200 is configured to store computer-executable instructions or program code, program data, and/or other suitable forms of information. A program 1210 stored on the computer-readable storage medium 1200 includes a set of instructions executable by the processor 1100. In an embodiment, the computer-readable storage medium 1200 may include a memory (a volatile memory such as a random access memory, a non-volatile memory, or a suitable combination thereof), one or more magnetic disk storage devices, optical disk storage devices, flash memory devices, other forms of storage media that can be accessed by the computing device 1000 and store desired information, or suitable combinations thereof.

The communication bus 1300 interconnects various other components of the computing device 1000, including the processor 1100 and the computer-readable storage medium 1200.

The computing device 1000 may also include one or more input/output interfaces 1500 and one or more network communication interfaces 1600 providing an interface for one or more input/output devices 2000. The input/output interface 1500 and the network communication interface 1600 are connected to the communication bus 1300. The network may be either a cellular network, such as a global system for mobile communications (GSM), enhanced data rates for GSM evolution (EDGE), a general packet radio service (GPRS), a code division multiple access (CDMA), a time division CDMA(TD-CDMA), a universal mobile telecommunications system (UMTS), a long term evolution (LTE), or another cellular network.

The input/output device 2000 may be connected to other components of the computing device 1000 through the input/output interface 1500. The exemplary input/output device 2000 may include an input device such as a pointing device (a mouse, a trackpad, or the like), a keyboard, a touch input device (a touchpad, a touchscreen, or the like), a voice or sound input device, various types of sensor devices, and/or a photographing device, and an output device such as a display device, a printer, a speaker, and/or a network card. The exemplary input/output device 2000 may be included inside the computing device 1000 as a component constituting the computing device 1000, or may be connected to the computing device 1000 as a separate device, distinct from the computing device 1000.

Meanwhile, embodiments of the present disclosure may include a program for performing the methods described in this specification on a computer, and a computer readable recording medium including the program. The computer-readable recording medium may include program instructions, local data files, local data structures, or the like, alone or in a combination thereof. The medium may be specially designed and configured for the present disclosure, or may be commonly available in the field of computer software. Examples of the computer-readable medium may include a hardware device specially configured to store a magnetic medium such as hard disks, floppy disks and magnetic tapes, an optical recording medium such as CD-ROMs and DVDs, and program instructions such as ROM, RAM, and a flash memory and perform the same. Examples of the program may include not only machine language codes generated by a compiler, but also high-level language codes that may be executed by a computer using an interpreter.

As set forth above, according to an aspect of the present disclosure, in a process of producing a slurry for an electrode of a secondary battery, a coagulable raw material (e.g., a binder) may be automatically extracted, metered, and injected into a slurry mixer.

In addition, compared to the existing manual work method, it can reduce the number of workers, thereby reducing manufacturing costs, and can improve work efficiency by reducing human errors and measurement errors.

The aforementioned description merely illustrates the technical concept of the present disclosure, and a person skilled in the art to which the present invention pertains may make various modifications and modifications without departing from the essential characteristics of the present disclosure.

Therefore, the example embodiments disclosed in this specification and drawings are not intended to limit but to explain the technical concept of the present disclosure, and the scope of the technical idea of the present disclosure is not limited by these example embodiments. The scope of protection of the present disclosure should be interpreted by the following claims, and all technical ideas within the scope equivalent thereto should be interpreted as being included in the scope of the present disclosure.

What is claimed is:

1. A system for integrated supply of coagulant raw materials, comprising:
a main storage tank for storing and metering a coagulable raw material;
a circulation pumping pipe providing a circulation path of the coagulable raw material from one end of the main storage tank to the other end thereof;
an extraction valve for extracting a portion of the coagulable raw material from the circulation pumping pipe for injection into a designated mixing line, when a mixing line for injection thereinto is designated;
a metering tank connected to the extraction valve, and metering the coagulable raw material extracted from the extraction valve; and
a compressed air injection nozzle connected to the metering tank, and supplying compressed air to the metering tank so that when the coagulable raw material metered in the metering tank reaches a target amount, the metered coagulable raw material is injected into the designated mixing line, after the extraction is stopped.

2. The system for integrated supply of coagulant raw materials of claim 1, further comprising:
a control device controlling loop line circulation, extraction and metering, and injection of the coagulable raw material, when a supply process of the coagulable raw material is initiated.

3. The system for integrated supply of coagulant raw materials of claim 2, wherein the main storage tank comprises
a stirrer disposed inside the main storage tank, to stir a coagulable raw material stored in the main storage tank; and
a first weight measuring device of measuring a weight of the coagulable raw material stored in the main storage tank.

4. The system for integrated supply of coagulant raw materials of claim 2, wherein the circulation pumping pipe comprises:
a circulation pipe connected from one end of the main storage tank to the other end thereof, and providing a loop line for circulation of the coagulable raw material stored in the main storage tank; and
a circulation pump disposed in the circulation pipe, and pumping the coagulable raw material from the main storage tank to circulate through the circulation pipe.

5. The system for integrated supply of coagulant raw materials of claim 2, wherein the extraction valve comprises
a branch pipe connected to a lower portion of the circulation pumping pipe in different locations thereof;
a branch valve disposed in the branch pipe, to open and close the branch pipe; and
a flexible pipe disposed in front of the branch valve, to flexibly connect the branch pipe from the influence of a weight of the circulation pumping pipe.

6. The system for integrated supply of coagulant raw materials of claim 2, wherein the metering tank comprises
a metering storage tank connected to the extraction valve, and storing a coagulable raw material introduced through the extraction valve;
a second weight measuring device for measuring a weight of the coagulable raw material stored in the metering storage tank;
a discharge pipe connected to one side of the metering storage tank, and discharging the metered coagulable raw material to a connected mixer; and
a metering valve disposed in the discharge pipe, and operating to meter and discharge the coagulable raw material.

7. The system for integrated supply of coagulant raw materials of claim 2, wherein the compressed air injection nozzle comprises:
an air injection nozzle connected between an inlet of the metering tank and a compressed air tank to inject compressed air; and
an air control valve disposed in the air injection nozzle, to open and close the air injection nozzle.

8. The system for integrated supply of coagulant raw materials of claim 2, wherein the control device comprises
a first controller, controlling circulation of a coagulable raw material through the circulation pumping pipe, when a supply process of the coagulable raw material is initiated;
a second controller, controlling extraction and metering of the coagulable raw material through the extraction valve and the metering tank, in relation to the corresponding mixing line, according to an injection request for the corresponding mixing line; and
a third controller, controlling injection of the coagulable raw material through the compressed air injection nozzle, in relation to the corresponding mixing line, when the metering is normally completed.

9. A method for integrated supply of coagulant raw materials, comprising:
performing a circulation pumping operation of performing mixing of a coagulable raw material stored in a main storage tank, and performing circulation of the coagulable raw material through a circulation pumping pipe, when a supply process of the coagulable raw material is initiated;
performing an injection request confirmation operation of confirming designation of a mixing line to be metered, when an injection request for a specific mixing line has been received;
performing a metering operation of performing extraction and metering through an extraction valve and a metering tank, for the designated mixing line; and
performing an injection operation of performing injection of the coagulable raw material into the corresponding mixing line using compressed air, when the metering is normally completed.

10. The method for integrated supply of coagulant raw materials of claim 9, wherein the circulation pumping operation comprises
a circulation pumping operation of initiating an operation of a circulation pump to circulate the coagulable raw material through a circulation pipe of the circulation pumping pipe, when a supply process of the coagulable raw material is initiated; and
a circulation maintenance operation of maintaining loop line circulation through the circulation pipe and the circulation pump.

11. The method for integrated supply of coagulant raw materials of claim 9, wherein the injection request confirmation operation comprises:
an injection request confirmation operation for determining whether an injection request for a specific mixing line has been received from a mixing control system; and
a mixing line designation confirmation operation for confirming the designation of a corresponding mixing line to be metered, when the injection request has been received.

12. The method for integrated supply of coagulant raw materials of claim 9, wherein the metering operation comprises:
an extraction valve opening operation, opening an extraction valve in relation to the corresponding mixing line;
a first metering verification operation, initiating metering of a coagulable raw material through the extraction valve, and performing first verification based on a first metering value for the coagulable raw material in the main storage tank; and
a second metering verification operation, performing second verification based on a second metering value for the coagulable raw material in the metering tank, when the first verification is normal.

13. The method for integrated supply of coagulant raw materials of claim 9, wherein the injection operation includes
an extraction stop operation, performing closing of the extraction valve in relation to the corresponding mixing line, when the metering is normally completed;
an air valve opening operation, performing opening of an air control valve connected to an air injection nozzle connected to an inlet of the metering tank; and
a coagulable raw material injection operation, injecting compressed air through the open air injection nozzle into the metering tank, and performing injection of the coagulable raw material in the metering tank into the designated mixing line.
